(19) United States
(12) Patent Application Publication
(10) Pub. No.: US 2005/0083217 A1
(43) Pub. Date: Apr. 21, 2005

(54) Method for transmitting and receiving signals in semiconductor device and semiconductor device thereof

(76) Inventors: Hong-Beom Kim, Gyeonggi-do (KR); Sung-Hwan In, Seoul (KR); Hee-Jun Lee, Gyeonggi-do (KR)

Correspondence Address: MARGER JOHNSON & MCCOLLOM, P.C., 1030 SW MORRISON STREET, PORTLAND, OR, 97205, US

(21) Appl. No.: 10/954,522

(22) Filed: Sep. 29, 2004

(30) Foreign Application Priority Data
Oct. 16, 2003 (KR) 2003-72172

(51) Int. Cl. H03M 5/08

(52) U.S. Cl. 341/53

(57) ABSTRACT

A method of transmitting and receiving a plurality of signals over a single transmission line in a semiconductor device and a semiconductor device are provided. The method includes encoding a plurality of original signals into signals having different pulse widths, combining the plurality of encoded signals into one signal and transmitting the one combined signal over the single transmission line, and receiving the combined signal and decoding the combined signal into the plurality of original signals.

### BACKGROUND OF THE INVENTION

This application claims the priority of Korean Patent Application No. 10-2003-72172 filed on Oct. 16, 2003, in the Korean Intellectual Property Office, the disclosure of which is incorporated herein in its entirety by reference.

1. Field of the Invention

The present invention relates to a method of transmitting and receiving signals in a semiconductor device and a semiconductor device thereof, and more particularly to a method of transmitting and receiving a plurality of signals over a single transmission line in a semiconductor device and a semiconductor device thereof.

2. Description of the Related Art

In recent years, advances in integrated circuit fabrication techniques have allowed semiconductor devices to be more densely packed with an increasing number of metal-oxide-semiconductor (MOS) transistors. Also, with the development of semiconductor devices shrinking to submicron levels, the number of wirings for transmitting and receiving signals has been drastically increasing. Accordingly, wirings for transmitting and receiving signals have become increasingly important in the overall semiconductor fabrication technology.

FIG. 1 is a block diagram illustrating a conventional method of transmitting and receiving a plurality of signals in a semiconductor device. Referring to FIG. 1, input signals A0, A1, . . . , An, e.g., address signals, are applied to an input buffer 1, and one-function block circuits 11 and 21 are activated by a control signal supplied from a controller 2 prior to signal transmission. To transmit a plurality of signals S1 and S2 from the one-function block circuits 11 and 21 to other function block circuits 12 and 22, a plurality, equal in number to the signals to be transmitted, of transmission lines TL1 and TL2 are required.

In particular, in order to control various operating modes of a synchronous semiconductor memory device, e.g., a synchronous dynamic random access memory (SDRAM), mode register set (MRS) signals are required. There are numerous kinds of MRS signals, including signals prescribed under the standard specification for each synchronous semiconductor memory device, such as a column address select (CAS) latency signal, a burst length signal, or a delay locked loop (DLL) reset signal, and signals associated with failure analysis or test for the synchronous semiconductor memory device.

Thus, in order to transmit the MRS signals, as many transmission lines as there are MRS signals are required. However, the requirement of having as many transmission lines as there are MRS signals has resulted in an increase in the overall area of the semiconductor device.

In an attempt to reduce the number of transmission lines required, there has been proposed an encoding method in which a plurality of signals are encoded into signals having different voltage levels, and then combined into one signal before being transmitted over a single transmission line. The combined signal is split into a plurality of signals to be decoded. The proposed technique is disclosed in Japanese Patent Laid-Open Publication No. 1999-27328.

However, the above disclosed encoding method presents several problems. For example, when the number of signals used for the semiconductor device increases, one of the encoded signals will have an unduly high voltage, so that a need arises to provide a separate voltage source. Also, the semiconductor device may become vulnerable to various types of thermal stress, and power consumption undesirably increases.

### SUMMARY OF THE INVENTION

The present invention provides a method of transmitting and receiving a plurality of signals over a single transmission line in a semiconductor device without increasing the overall area of the semiconductor device.

The present invention also provides a method of transmitting and receiving a plurality of signals over a single transmission line in a semiconductor device without using a separate voltage source.

The present invention provides a semiconductor device for transmitting and receiving a plurality of signals over a single transmission line in the semiconductor device without increasing the overall area thereof.

The present invention also provides a semiconductor device for transmitting and receiving a plurality of signals over a single transmission line in the semiconductor device without using a separate voltage source.

In a first embodiment of the present invention, there is provided a method for transmitting and receiving a plurality of signals over a single transmission line in a semiconductor device, the method comprising encoding the plurality of signals into signals having different pulse widths, combining the plurality of encoded signals together to produce a combined, or single, signal, and transmit the same over a single transmission line, receiving the combined signal and decoding the combined signals into the original plurality of signals.

In a second embodiment of the present invention, there is provided a semiconductor device comprising an encoder that encodes a plurality of original signals into signals having different pulse widths, a combiner that combines the plurality of encoded signals together to produce a combined, or single, signal, and a receiver that decodes the combined signal into the plurality of the original signals.

In a third embodiment of the present invention, there is provided a semiconductor device comprising an encoder that encodes a plurality of original signals into signals having different pulse widths, and a combiner that combines the plurality of encoded signals together to produce a combined, or single, signal.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional semiconductor device illustrating a method for transmitting and receiving a plurality of signals;

FIG. 2 is a block diagram illustrating a semiconductor device according to the present invention;

FIG. 3A is a timing diagram illustrating a method of encoding a plurality of signals in the semiconductor device according to the present invention;

FIG. 3B is a timing diagram illustrating a method of decoding a plurality of signals in the semiconductor device according to the present invention;

FIG. 4 is a circuit diagram of an encoder of the semiconductor device according to the present invention;

FIG. 5 is a circuit diagram of a combiner of the semiconductor device according to the present invention;

FIG. 6 is a circuit diagram of a splitter of the semiconductor device according to the present invention; and

FIG. 7 is a circuit diagram of a decoder of the semiconductor device according to the present invention.

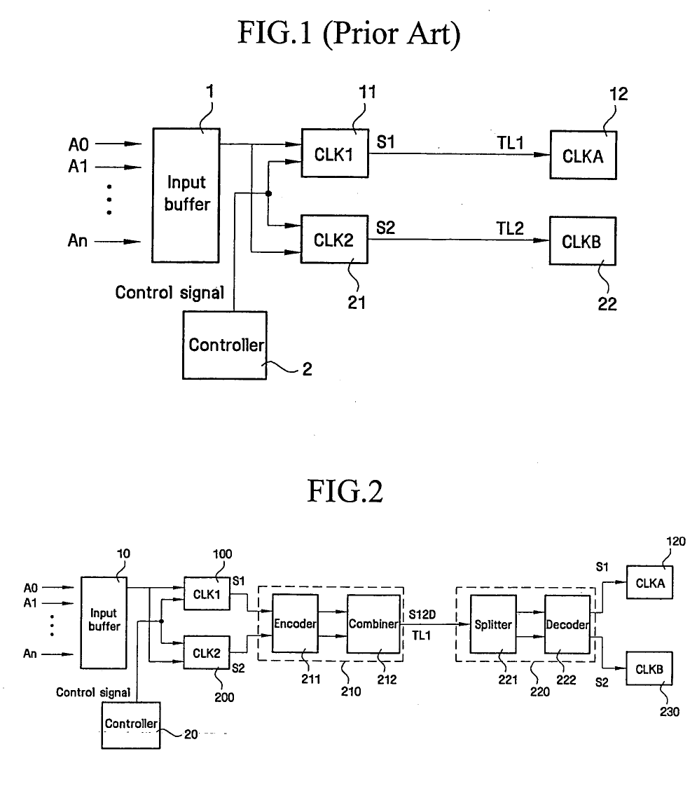

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

FIG. 2 is a block diagram illustrating a semiconductor device according to the present invention. As shown in FIG. 2, input signals A0, A1, . . . , An, e.g., address signals, are applied to an input buffer 10, and a plurality of function block circuits 100 and 200 are activated by a control signal supplied from a controller 20 prior to signal transmission. When a plurality, e.g., two, of signals S1 and S2 are to be transmitted from the plurality of function block circuits 100 and 200 to another plurality of function block circuits 120 and 230, the signals S1 and S2 are combined into one signal S12D through an encoder 211 and a combiner 212 so as to be transmitted over a single transmission line TL1.

The combined signal S12D is split into the plurality of signals S1 and S2 through a splitter 221 and a decoder 222, thereby enabling the plurality of signals S1 and S2 to be transmitted over the single transmission line TL1.

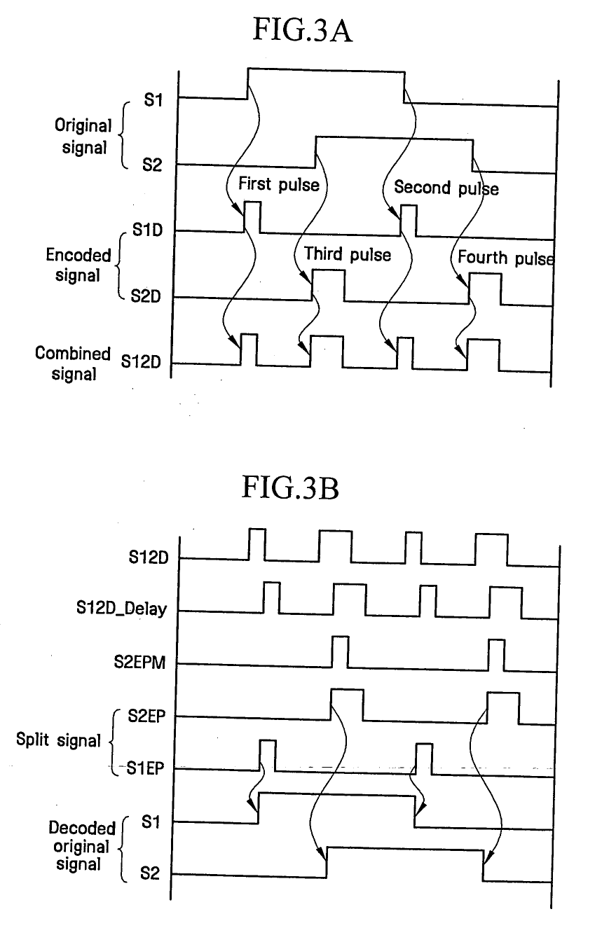

FIG. 3A is a timing diagram illustrating a method of encoding a plurality of signals in the semiconductor device according to the present invention.

When a plurality of original signals is to be transmitted in a semiconductor device, the plurality of original signals is encoded into signals having different pulse widths.

As shown in FIG. 3A, an activation time of one signal S1 of a plurality of original signals S1 and S2 is detected to generate a first pulse signal having a first pulse width, e.g., 1 nanosecond (ns), and a deactivation time of the signal S1 is detected to generate a second pulse signal having the first width of 1 ns. Then, the first and second pulse signals are encoded into one encoded signal S1D having the first pulse width. That is to say, every two pulse signals are generated from each signal to be transmitted.

In the same manner as described above, activation and deactivation times of the other signal S2 of the plurality of original signals S1 and S2 are detected to generate third and fourth pulse signals each having a second pulse width, e.g., 2 ns, to then be encoded into the other encoded signal S2D.

In detail, pulse signals are generated by detecting activation times of the plurality of original signals S1 and S2. The detecting of activation times is achieved by performing an AND operation on the plurality of original signals S1 and S2 and delayed inverse signals thereof.

Also, other pulse signals are generated by detecting deactivation times of the plurality of original signals S1 and S2. The detecting of deactivation times is achieved by performing an AND operation on inverse signals of the plurality of original signals S1 and S2 and delayed signals thereof.

Preferably, the pulse widths of the pulse signals generated by detecting activating times of each signal among the plurality of signals are adjusted to be the same with those of the pulse signals generated by detecting deactivation times thereof, thereby enabling one signal to be easily distinguished from another.

Next, the plurality of encoded signals S1D and S2D are combined into one signal S12D to then be transmitted over a single transmission line TL1. The encoded signals S1D and S2D can be easily combined into one combined signal S12D by performing an exclusive OR operation on the encoded signals S1D and S2D. An OR operation can also be used in combining the encoded signals S1D and S2D, thus easily producing the combined signal S12D.

FIG. 3B is a timing diagram illustrating a method of decoding a plurality of signals in the semiconductor device according to the present invention.

Now, the combined signal S12D is received and split into a plurality of split signals S1EP and S2EP.

As shown in FIG. 3B, an AND operation is performed on the combined signal S12D and its delayed signal S12D_Delay, obtained by delaying the combined signal S12D by a predetermined delay time, to generate a pre-split intermediate signal S2EPM. One of the pulse widths of each signal of the plurality of encoded signals S1D and S2D is used as the predetermined delay time.

Next, the timing of the pre-split intermediate signal S2EPM making a transition from a logic high to a logic low, is delayed, thereby generating a second split signal S2EP, which is the same as one of the encoded signals S1D and S2D.

The second split signal S2EP can be easily obtained by performing an OR operation on the pre-split intermediate signal S2EPM and a delayed signal thereof. When the pre-split intermediate signal S2EPM is in a logically high state, an output signal of the OR operation is maintained at a high state. However, if the pre-split intermediate signal S2EPM makes a transition from a logic high to a logic low, the output signal of the OR operation is maintained at a logic high by the delay time of the pre-split intermediate signal S2EPM. In such a manner, the timing of the pre-split intermediate signal S2EPM making a transition from a logic high to a logic low is delayed.

Then, an exclusive OR operation is performed on the delayed signal of the combined signal S12D, S12D_Delay, and the second split signal S2EP, thereby generating the first split signal S1EP. The thus obtained first split signal S1EP is the same as one of the signals S1D and S2D.

Next, the first and second split signals S1EP and S2EP are decoded into the original signals S1 and S2. The decoded signal S1 is activated by the first pulse of the first split signal S1EP and deactivated by the second pulse signal of the first split signal S1EP. The decoded signal S1 is the same as one of the plurality of signals S1 and S2.

Another decoded signal S2, which is activated by the first pulse of the second split signal S2EP and deactivated by the second pulse signal of the second split signal S2EP, is generated by the same method as the generation of the decoded signal S1. The decoded signal S2 is the same as one of the plurality of signals S1 and S2.

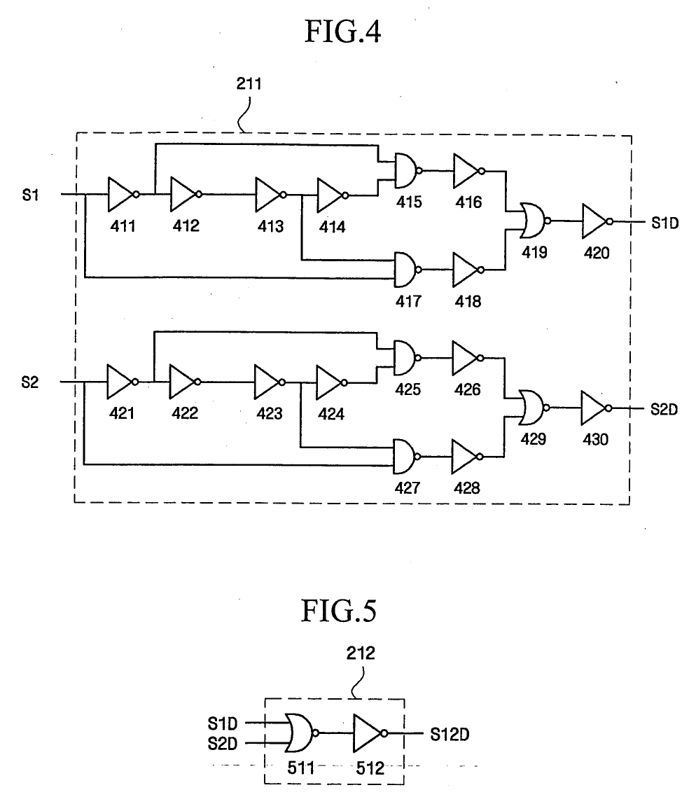

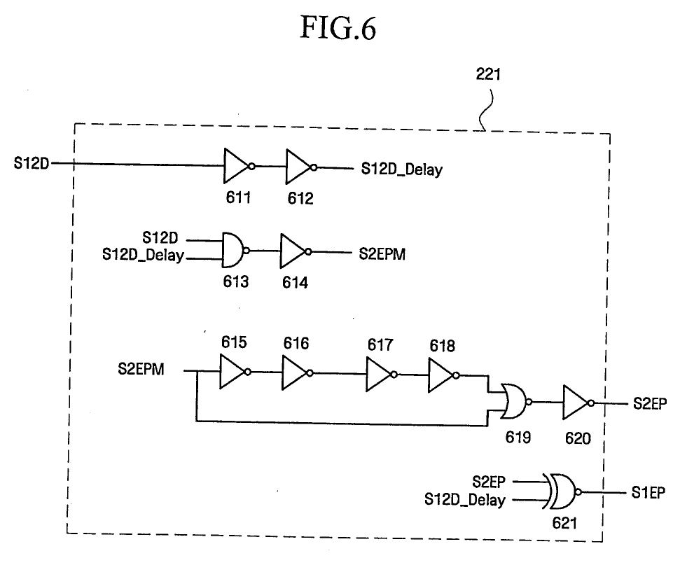

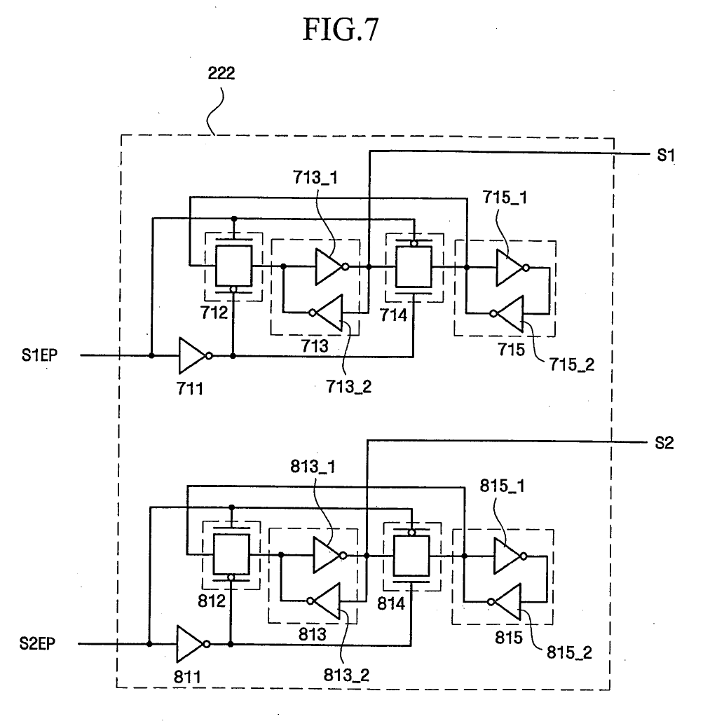

FIGS. 4 through 7 are diagrams of various circuits of the semiconductor device according to the present invention, in which FIG. 4 is a circuit diagram of an encoder 211 of the semiconductor device according to the present invention, FIG. 5 is a circuit diagram of a combiner 212 of the semiconductor device according to the present invention, FIG. 6 is a circuit diagram of a splitter 221 of the semiconductor device according to the present invention, and FIG. 7 is a circuit diagram of a decoder 222 of the semiconductor device according to the present invention.

Referring back to FIG. 2, the semiconductor device according to the present invention includes a transmitter 210 and a receiver 220. The transmitter 210 includes an encoder 211 and a combiner 212. The receiver 220 includes a splitter 221 and a decoder 222. The encoder 211 encodes a plurality of signals into signals having different pulse widths. The combiner 212 combines a plurality of encoded signals into one signal. The splitter 221 splits the combined signal into the plurality of encoded signals. The decoder 222 decodes the plurality of encoded signals into a plurality of signals.

Turning now to FIG. 4, the encoder 211 detects activation and deactivation times of the plurality of signals S1 and S2 and produces encoded signals S1D and S2D each having two pulses.

In order to produce first and third pulse signals by detecting activation times of the respective signals S1 and S2, as shown in FIG. 4, an AND operation is performed on the respective signals S1 and S2 and delayed inverse signals thereof by means of AND gates 417, 418, 427 and 428. A NAND operation can also be used in producing the first and third pulse signals by detecting activation times of the plurality of signals S1 and S2.

The delayed inverse signals of the signals S1 and S2 can be easily obtained by passing each signal S1, S2 through an odd number of inverters 411 through 413, 421 through 423 connected in series.

The delayed inverse signals of the signals S1 and S2 can also be obtained by means of NAND gates or NOR gates having a plurality of input terminals connected together, rather than by means of the inverters.

When the signals S1 and S2 maintain a logic low state, output signals of the AND gates 417, 418, 427 and 428 are kept at a logic low. However, when the signals S1 and S2 make a transition from a logic low to a logic high, the output signals of the AND gates 417, 418, 427 and 428 transition to a logic high after the delay time of the delayed inverse signals of the signals S1 and S2. Thus, the first and third pulse signals are produced by detecting activation times of the plurality of signals S1 and S2, respectively.

Since the pulse widths of the produced first and third pulse signals are determined by the delay time of the delayed inverse signals of the signals S1 and S2, they can be easily adjusted by adjusting the odd number of inverters that are connected in series.

In order to produce second and fourth pulse signals by detecting deactivation times of the respective signals S1 and S2, an AND operation is performed on inverse signals of the respective signals S1 and S2 and delayed signals thereof by means of AND gates 415, 416, 425 and 426. An OR operation can also be used in producing the second and fourth pulse signals by detecting deactivation times of the plurality of signals S1 and S2.

The delayed signals of the signals S1 and S2 can be easily obtained by passing each signal S1, S2 through an even number of inverters 411 through 414, 421 through 424 connected in series. As described above, the delayed signals of the signals S1 and S2 can also be obtained by means of NAND gates or NOR gates having a plurality of input terminals connected together, rather than by means of the inverters.

When the signals S1 and S2 maintain a logic high state, the output signals of the AND gates 415, 416, 425 and 426 are kept at a logic low. However, when the signals S1 and S2 make a transition from a logic high to a logic low, the output signals of the AND gates 415, 416, 425 and 426 transition to a logic high after the delay time of the delayed signals of the signals S1 and S2. Thus, the second and fourth pulse signals are produced by detecting deactivation times of the plurality of signals S1 and S2, respectively.

Since the pulse widths of the produced second and fourth pulse signals are determined by the delay time of the delayed signals of the respective signals S1 and S2, they can be easily adjusted by adjusting the even number of inverters 411 through 414, 421 through 424 that are connected in series.

An OR operation is performed on the output signals of the AND gates 415, 416, 425 and 426 and the output signals of the AND gates 417, 418, 427 and 428 by means of OR gates 419, 420, 429 and 430 to detect activation and deactivation times of the signals S1 and S2, thereby producing encoded signals S1D and S2D each having two pulses.

The pulse widths of the first and third pulse signals produced by detecting activation times of the plurality of signals S1 and S2 are preferably adjusted to be the same as those of the second and fourth pulse signals generated by detecting deactivation times thereof, thereby enabling one of the respective signals S1 and S2 to be easily distinguished from the other.

As shown in FIG. 5, the combiner 212 combines the plurality of encoded signals S1D and S2D into one combined signal S12D by passing the encoded signals through OR gates 511 and 512.

As shown in FIG. 6, the splitter 221 produces a pre-split intermediate signal S2EPM by performing an AND operation on the combined signal S12D and its delayed signal S12D_Delay by means of AND gates 613 and 614. The delayed signal S12D_Delay can be easily obtained by passing the combined signal S12D through an even number of inverters 611 and 612 connected in series. The delay time of the delayed signal S12D_Delay can be adjusted by the even number of inverters 611 and 612 connected in series. One of the pulse widths of the plurality of encoded signals S1D and S2D is used as the delay time of the delayed signal S12D_Delay of the combined signal S12D.

Next, the second split signal S2EP, which is the same as one of the plurality of encoded signals S1D and S2D, is produced by delaying the time of the logic high to low transition of the pre-split intermediate signal S2EPM.

The second split signal S2EP can be easily generated by performing an OR operation on the pre-split intermediate signal S2EPM and a delayed pre-split intermediate signal S2EPM by means of OR gates 619 and 620. The delayed signal of the pre-split intermediate signal S2EPM can be easily obtained by passing the pre-split intermediate signal S2EPM through an even number of inverters 615 through 618 connected in series. The delay time of the delayed signal of the pre-split intermediate signal S2EPM can be adjusted by the even number of inverters 615 through 618 connected in series.

When the pre-split intermediate signal S2EPM maintains a logic high state, the output signal of the OR gates 619 and 620 is kept at a logic high. However, when the pre-split intermediate signal S2EPM makes a transition from a logic high to a logic low, the output signal of the OR gates 619 and 620 continues to maintain a logic high by a delay time of the delayed signal of the pre-split intermediate signal S2EPM. In such a manner, the time that the pre-split intermediate signal S2EPM makes a transition from logic high to low is delayed.

Next, the first split signal S1EP is generated by performing an exclusive OR operation on the delayed signal S12D_Delay and the second split signal S2EP by means of an exclusive OR gate 621. That is, the first split signal S1EP is the same as one of the plurality of encoded signals S1D and S2D.

The decoder 222 decodes the plurality of split signals S1EP and S2EP back into the plurality of original signals S1 and S2, since the plurality of the original encoded signals is equivalent to the plurality of encoded signals input to the decoder. A decoded signal is produced that is activated by the first pulse signal of the second split signal S2EP and deactivated by the second pulse signal thereof. The decoded signal is the same as one of the plurality of original signals S1 and S2.

Another decoded signal that is activated by the first pulse signal of the first split signal S1EP and deactivated by the second pulse signal thereof is generated by the same method as described above. The decoded signal is the same as one of the plurality of original signals S1 and S2.

As shown in FIG. 7, the decoder 222 includes first transmission gates 714 and 814, second transmission gates 712 and 812, first inverse latches 715 and 815, and second inverse latches 713 and 813.

The first inverse latches 715 and 815 include first inverters 715_1 and 815_1, and second inverters 715_2 and 815_2 latched to the first inverters 715_1 and 815_1, respectively. The second inverse latches 713 and 813 include third inverters 713_2 and 813_2, and fourth inverters 713_1 and 813_1 latched to the third inverters 713_2 and 813_2, respectively.

The first transmission gates 714 and 814, which responds to the first and second split signals, S1EP and S2EP, respectively, can transmit output signals of the fourth inverters 713_1 and 813_1 to input terminals of the first inverters 715_1 and 815_1, respectively. The second transmission gates 712 and 812, which respond to the first and second split signals, S1EP and S2EP, can transmit output signals of the second inverters 715_2 and 815_2 to input terminals of the fourth inverters 713_1 and 813_1, respectively.

Referring back to FIG. 3B, when the second split signal S2EP and the first split signal S1EP are at logic low state, the first transmission gates 714 and 814 are activated and the second transmission gates 712 and 812 are deactivated, respectively. Thus, the output signals of the fourth inverters 713_1 and 813_1 are transmitted to the input terminals of the first inverters 715_1 and 815_1, while the output signals of the second inverters 715_2 and 815_2 are not transmitted to the input terminals of the fourth inverters 713_1 and 813_1, respectively.

Therefore, the output signals of the fourth inverters 713_1 and 813_1 maintain initially set states, which are further ensured by the third inverters 713_2 and 813_2 latched to the fourth inverters 713_1 and 813_1, respectively.

When the first pulse signals of the second split signal S2EP and the first split signal S1EP are applied to the first transmission gates 714 and 814, the first transmission gates 714 and 814 are deactivated and the second transmission gates 712 and 812 are activated, respectively. Thus, the output signals of the second inverters 715_2 and 815_2 are transmitted to the input terminals of the fourth inverters 713_1 and 813_1 while the output signals of the fourth inverters 713_1 and 813_1 are not transmitted to the input terminals of the first inverters 715_1 and 815_1, respectively.

Therefore, the fourth inverters 713_1 and 813_1 invert initially set states, so that the output signals of the fourth inverters 713_1 and 813_1 maintain a logic low state, which is further ensured by the third inverters 713_2 and 813_2, respectively.

Also, while the second split signal S2EP and the first split signal S1EP maintain a logic low state, the second transmission gates 712 and 812 are deactivated, and the output signals of the fourth inverters 713_1 and 813_1 are kept at a logic high state, respectively.

When the second pulse signals of the second split signal S2EP and the first split signal S1EP are applied to the first transmission gates 714 and 814, the first transmission gates 714 and 814 are deactivated and the second transmission gates 712 and 812 are activated, respectively. Thus, the output signals of the second inverters 715_2 and 815_2 are transmitted to the input terminals of the fourth inverters 713_1 and 813_1 while the output signals of the fourth inverters 713_1 and 813_1 are not transmitted to the input terminals of the first inverters 715_1 and 815_1, respectively.

Therefore, the fourth inverters 713_1 and 813_1 invert initially set states, so that the output signals of the fourth inverters 713_1 and 813_1 maintain a logic low state, which is further ensured by the third inverters 713_2 and 813_2, respectively. Thus, the decoded signals can be easily obtained by using the output signals of the fourth inverters 713_1 and 813_1 as the decoded signals, respectively.

As described above, according to the present invention, a plurality of signals can be transceived over a single transmission line in a semiconductor device without increasing the overall area of the semiconductor device.

Also, a plurality of signals can be transceived over a single transmission line in a semiconductor device without using a separate high voltage source.

While specific embodiments of the invention have been described, the scope of the invention is defended by the claims that follow, rather than the details given herein and it should be recognized that various modifications, alterations, and equivalents are encompassed within the scope of the present invention.

1. A method of transmitting and receiving a plurality of original signals over a single transmission line in a semiconductor device, the method comprising:
encoding the plurality of original signals into signals having different pulse widths;
combining the plurality of encoded signals into a single signal and transmitting the single signal over the single transmission line; and
receiving the single signal and decoding the single signal into the plurality of original signals.

2. The method of claim 1, wherein the transmitting comprises combining the plurality of encoded signals into the single signal by performing an OR operation thereon.

3. The method of claim 1, wherein the receiving comprises:
receiving the single signal and splitting the same into split signals; and
decoding the split signals into the plurality of original signals.

4. The method of claim 1, wherein the decoding comprises generating a decoded signal that is activated by a first pulse signal of each of the plurality of encoded signals and deactivated by a second pulse signal thereof.

5. The method of claim 3, wherein the splitting comprises:
performing an AND operation on the single signal and its delayed signal delayed by a predetermined time, and generating a pre-split intermediate signal;
delaying a time of the pre-split intermediate signal making a transition from a logic high to a logic low, and generating a second split signal that is the same as one of the plurality of encoded signals; and
performing an exclusive OR operation on the delayed signal of the single signal and the second split signal, and generating a first split signal that is the same as another of the plurality of encoded signals.

6. The method of claim 1, wherein the encoding comprises detecting respective activation and deactivation times of the plurality of original signals and generating pulse signals at the respective times.

7. The method of claim 6, wherein the pulse signals are generated by detecting respective activation times of the plurality of original signals by performing an AND operation on each original signal and a delayed inverse signal thereof.

8. The method of claim 6, wherein the pulse signals are generated by detecting respective deactivation times of the plurality of original signals by performing an AND operation on an inverse signal of each original signal and a delayed signal thereof.

9. The method of claim 7, wherein pulse widths of the pulse signals generated by detecting activation times of the plurality of original signals are adjusted to be the same as those generated by detecting deactivation times of the plurality of original signals.

10. The method of claim 8, wherein pulse widths of the pulse signals generated by detecting activation times of the plurality of original signals are adjusted to be the same as those generated by detecting deactivation times of the plurality of original signals.

11. A semiconductor device comprising:
an encoder that encodes a plurality of original signals into signals having different pulse widths;
a combiner that combines the plurality of encoded signals together to produce a single signal; and
a receiver that decodes the single signal into the plurality of the original signals.

12. The semiconductor device of claim 11, wherein the encoder detects respective activation and deactivation times of the plurality of original signals and generates pulse signals at the respective times.

13. The semiconductor device of claim 12, wherein the encoder generates the pulse signals by detecting respective activation times of the plurality of original signals by performing an AND operation on each original signal and a delayed inverse signal thereof.

14. The semiconductor device of claim 13, wherein the delayed inverse signal of each original signal is supplied by means of an odd number of inverters that are connected in series.

15. The semiconductor device of claim 14, wherein the pulse widths of the pulse signals are adjusted by adjusting the odd number of inverters that are connected in series.

16. The semiconductor device of claim 12, wherein the encoder generates the pulse signals by detecting respective deactivation times of the plurality of original signals by performing an AND operation on an inverse signal of each original signal and a delayed signal thereof.

17. The semiconductor device of claim 16, wherein the delayed signal of each original signal is supplied by means of an even number of inverters that are connected in series.

18. The semiconductor device of claim 17, wherein the pulse widths of the pulse signals are adjusted by adjusting the even number of inverters that are connected in series.

19. The semiconductor device of claim 12, wherein the pulse widths of the pulse signals generated by detecting respective activation times of each signal of the plurality of original signals are adjusted to be the same as those of the pulse signals generated by detecting respective deactivation times thereof.

20. The semiconductor device of claim 11, wherein the combiner combines the plurality of encoded signals into the single signal by performing an OR operation thereon.

21. The semiconductor device of claim 11, wherein the receiver comprises:
a splitter that receives the single signal and splits the same into split signals; and
a decoder that decodes the split signals into the plurality of original signals.

22. The semiconductor device of claim 21, wherein the splitter performs an AND operation on the single signal and its delayed signal delayed by a predetermined time to generate a pre-split intermediate signal, delays a time of the pre-split intermediate signal making a transition from a logic high to a logic low to generate a second split signal that is the same as one of the plurality of encoded signals, and performs an exclusive OR operation on the delayed signal of the single signal and the second split signal to generate a first split signal that is the same as another of the plurality of encoded signals.

23. The semiconductor device of claim 22, wherein the splitter generates the second split signal by performing an OR operation on the pre-split intermediate signal and a delayed signal thereof.

24. The semiconductor device of claim 21, wherein the decoder, which is activated by a first pulse signal of each of the plurality of encoded signals, and deactivated by a second pulse signal thereof, decodes the plurality of encoded signals into the plurality of original signals.

25. The semiconductor device of claim 21, wherein the decoder transmits an output signal of a first inverter and a second inverter latched to the first inverter to input terminals of a fourth inverter and a third inverter latched to the fourth inverter by the split signals, and transmits the output signal of the fourth inverter to an input terminal of the first inverter by the inverted split signals.

26. A semiconductor device comprising:
an encoder that encodes a plurality of original signals into signals having different pulse widths; and
a combiner that combines the plurality of encoded signals together to produce a single signal.

27. A semiconductor device comprising:
a splitter that splits a single signal into a plurality of encoded signals;
a decoder that decodes the plurality of encoded signals into a plurality of signals, wherein the single signal is generated by combining an original plurality of encoded signals generated by encoding a plurality of original signals into signals having different pulse widths; and
the plurality of encoded signals is equivalent to the original plurality of encoded signals.
